(19) United States
(12) Patent Application Publication
(10) Pub. No.: US 2013/0180773 A1
(43) Pub. Date: Jul. 18, 2013

(54) CIRCUIT SUBSTRATE STRUCTURE AND MANUFACTURING METHOD THEREOF

(71) Applicants: Cheng-Feng CHIANG, Taoyuan County (TW); Jung-Chuan CHIANG, Taoyuan County (TW)

(72) Inventors: Cheng-Feng CHIANG, Taoyuan County (TW); Jung-Chuan CHIANG, Taoyuan County (TW)

(21) Appl. No.: 13/533,702

(22) Filed: Jun. 26, 2012

(30) Foreign Application Priority Data
Jan. 18, 2012 (CN) 201210016458.7
Jan. 18, 2012 (CN) 201220024346.1

(51) Int. Cl. H05K 1/02; C25D 5/02; H05K 3/10

(52) U.S. Cl. 174/268; 427/98.8; 427/555; 205/125

(57) ABSTRACT

A method for manufacturing circuit substrate structure and its product are provided. Firstly, an attached enhancement portion having rough surfaces is formed on a surface of a carrier through a roughing process, and a catalyst is disposed on a surface of the attached enhancement portion. Finally, a metal layer is formed on the attached enhancement portion after reacting with the catalyst through chemical plating reduction. The foregoing manufacturing method can effectively reduce the usage of the catalyst or an accelerator to greatly decrease the using costs of the catalyst and the accelerator.

### CROSS-REFERENCE TO RELATED APPLICATION

This application claims the benefit of China Patent Application No. 201210016458.7, filed on Jan. 18, 2012, and No. 201220024346.1, filed on Jan. 18, 2012, in the State Intellectual Property Office of the People's Republic of China, the disclosure of which is incorporated herein in its entirety by reference.

### BACKGROUND OF THE INVENTION

1. Field of the Invention

The present invention relates to a circuit substrate structure and its manufacturing method, and more particularly to a manufacturing method for forming circuit substrate structure on non-conductive carriers.

2. Description of the Related Art

In view of diversity of 3C products, people may tend to focus on the convenience and portability of 3C products such that electronic products are developed to be toward small sizes, light weight and multifunctional directions. Simultaneously, IC design and its circuit design are advanced toward a direction of three-dimensional design. With three-dimensional circuit components, complicated circuits can be formed on circuit components with limited volumes. The appearance and volumes of electronic products can be reduced under a condition of no influencing its functions so as to further shrink and reduce weights. In another word, complicated design in three-dimensional circuit components can be remained under the smaller volume of electronic products. Therefore, the three-dimensional design of circuit components exactly has multiple potentials to reduce sizes and weight of electronic products and have multifunction, thereby having higher product competitiveness and can be widely applied to different devices such as mobile phones, automobile circuits, automatic teller machines and hearing aids.

Currently, in different ways of producing three-dimensional circuit components, one is MID-LDS (molded interconnect device-laser direct structuring). The foregoing way is to inject-mold a non-conductive plastic material containing a catalyst to form a component carrier. The catalyst on the carrier is activated by laser to transform the catalyst into a catalyst core. A metal conductive circuit is formed since the catalyst core and pre-plated metal ions are performed with chemical plating reaction.

The design of conductive circuit structures in the foregoing three-dimensional circuit process is composed of many circuits that are not connected to each other. With the metal catalyst attached to a partial surface of the circuit components to be formed with conductive circuit patterns, the pre-plated metal ions existing in chemical plating solution is performed with a catalysis reaction to reduce pre-plated metal ions on the partial surface of the circuit component to be formed with circuit patterns. Therefore, chemical plating does not have non-uniformity in distributing power lines by comparing with electroplating and also obtains a plated layer having a uniform thickness with respect to plated members having complicated geometrical shapes. Currently, a conventional way usually adopts chemical plating to produce conductive circuits of three-dimensional circuit components.

Under a condition of no imposing power, chemical plating is to perform a catalysis reaction for pre-plated metal ions existing in chemical plating solution through the metal catalyst attached to a partial surface of the circuit components to be formed with circuit patterns so that pre-plated metal ions are reduced on the partial surface of the circuit components to be formed with circuit patterns. Accordingly, chemical plating can form the metal plated layer having uniform thickness on the partial surface of the circuit components to be formed with circuit patterns.

An objective of the conductive circuit structures in the three-dimensional circuit process is to achieve small sizes, light weight, multifunction and higher product competitiveness for electronic products, thereby having widely application potential to 3C electronic products. However, it may have the following restrictions and defects.
1. A conventional method for producing three-dimensional circuit components may need to add mass of catalysts into the non-conductive plastic material that is then injected and molded to form the carrier although it can effectively produce the conductive circuit structures in the three-dimensional circuit process. In MID-LDS process, the catalyst performing the reaction is only at the surface layer. However, the catalyst having a certain ratio must be added into the non-conductive plastic material to consume higher catalyst costs.
2. Mass of catalysts must be added into the non-conductive plastic material in MID-LDS process, and it is then injection-molded to form the carrier. Since the catalyst is uniformly distributed in the carrier. The metal core, which has been peeled off, on the surface requires reduction agent concentration having higher dosage in subsequent chemical plating process to smoothly plate the metal core. Relatively, chemical copper plating solution is unstable and needs to consume more chemical plating solution to perform chemical reduction reaction for the overall surface of the carrier, thereby forming desire conductive circuits of the three-dimensional circuits on the circuit components. However, the foregoing manner may spend higher costs in chemical plating solution.

Therefore, the current process technique of the three-dimensional circuits is still restricted with high production costs to be short of a conductive circuit structure and its manufacturing method applied to 3C electronic products.

### SUMMARY OF THE INVENTION

In view of the shortcomings of the prior art, the inventor(s) of the present invention based on years of experience in the related industry to conduct extensive researches and experiments, and finally developed a method for manufacturing circuit substrate structure as a principle objective that is suitable for circuit process of a non-conductive carrier. Firstly, a carrier is provided, and an attached enhancement portion having rough surfaces is formed on a surface of the carrier through roughing process. The characteristic of the attached enhancement portion is transformed into hydrophilicty from hydrophobicity. A catalyst is disposed on a surface of the attached enhancement portion of the carrier. Finally, a metal layer is formed to the attached enhancement portion by reacting with the catalyst through chemical plating reduction.

Preferably, the carrier can be a non-conductive carrier and is a material having heat conduction property, wherein the roughing process can be sand blasting or laser irradiation etching. Before performing the roughing process for the surface of the carrier, a catalyst insulation layer can be further disposed on the carrier, and the catalyst insulation layer is penetrated by using the roughing process manner to the surface of the carrier, and the attached enhancement portion is formed on the surface of the carrier.

Preferably, the material of the non-conductive carrier can be a ceramic material, a polymer plastic material, wherein the polymer plastic material can be a thermoplastic plastic material or a thermosetting plastic material. The ceramic material can be selected from a group consisting of oxide, nitride, carbide, and boride. Further, the ceramic material is selected from a group consisting of oxide, nitride, carbide, boride is combined with a binding agent to form a mixture capable of being injected and pressed. After forming the mixture, the binding agent is removed to sinter it.

Preferably, the catalyst can be selected from a group consisting of titanium, antimony, silver, palladium, iron, nickel, copper, vanadium, cobalt, zinc, platinum, iridium, osmium, rhodium, rhenium, ruthenium, tin, a mixture thereof and can also be a compound thereof.

Preferably, the polymer plastic material of the non-conductive carrier can be added with inorganic filler, wherein a constituent of the inorganic filler can be selected from a group consisting of silicic acid, silicic acid derivative, carbonic acid, carbonic acid derivative, phosphoric acid, phosphoric acid derivative, active carbon, porous carbon, carbon black, glass fabrics, carbon fabrics or mineral fabrics or a foregoing combination.

Preferably, the wavelength range of the foregoing laser irradiation can be between 248 nanometers and 10600 nanometers. The laser irradiation etching can be carbon dioxide (CO₂) laser, yttrium aluminum garnet (Nd:YAG) laser, yttrium orthovanadate (Nd:YVO₄) laser, excimer laser or fiber laser.

Preferably, the non-conductive carrier having heat conduction property comprises a material having heat conduction property or a derivative thereof dispersed therein. Further, the material having heat conduction property can be a metal heat conduction material. The metal heat conduction material can be selected from a group consisting of lead, aluminum, gold, copper, tungsten, magnesium, molybdenum, zinc, silver or a forgoing combination. The non-metal heat conduction material can be selected from a group consisting of graphite, graphite alkene, diamond, carbon nano-tube, carbon nano-capsule, nano-bubble, carbon sixty, carbon nano-cone, carbon nano-horn, carbon nano-pipet, tree-like carbon micrometer structure, beryllium oxide, aluminum oxide, zirconium oxide, boron nitride, aluminum nitride, magnesium oxide, silicon nitride, silicon carbide or a foregoing combination.

Preferably, at least one heat conduction column is embedded in the non-conductive carrier to increase the heat transfer efficiency of the non-conductive carrier. The material of the heat conduction column can be selected from a group consisting of lead, aluminum, gold, copper, tungsten, magnesium, molybdenum, zinc, silver, graphite, graphite alkene, diamond, carbon nano-tube, carbon nano-capsule, nano-bubble, carbon sixty, carbon nano-cone, carbon nano-horn, carbon nano-pipet, tree-like carbon micrometer structure, beryllium oxide, aluminum oxide, zirconium oxide, boron nitride, aluminum nitride, magnesium oxide, silicon nitride, silicon carbide or a foregoing combination.

Further, the foregoing manufacturing method can be utilized to simultaneously dispose at least one conductive contact on the carrier, which is disposed at an outside of the attached enhancement portion, through the roughing process after providing the carrier. The conductive contact is connected to an edge of the carrier to form an interlinked circuit together with the attached enhancement portion. The metal layer is disposed on the attached enhancement portion and the conductive contact through chemical electroplating. An anti-plating insulation layer is disposed on the conductive contact. Further, the electroplating layer is disposed on the attached enhancement portion by utilizing the electrifying and electroplating so as to increase the thickness of the metal layer. Finally, the anti-plating insulation layer and the metal layer disposed on the conductive contact are removed to obtain independently circuit patterns.

Preferably, the manufacturing method is suitable for three-dimensional circuit process of a plastic film component having heat conduction property. The carrier has heat conduction property. During electroplating process, the metal layer having conductivity generated by electroplating and electrifying is taken as a cathode, and an anode of a power source is jointed to a preplated metal solid. When the carrier component is immersed into electroplating solution containing preplated metal ions, the preplated metal ions are reduced to precipitate preplated metal on the metal layer when the metal layer taken as the cathode receives electrons, thereby forming the required metal circuits. The preplated metal can be copper, nickel, chromium, tin, silver or gold or other alloy metal.

The method for manufacturing circuit substrate structure can be widely applied to the three-dimensional circuit process of the non-conductive carrier, the non-conductive carrier having heat conduction property or the plastic film component having heat conduction property.

According to an objective of the invention, a method for manufacturing circuit substrate structure is utilized to produce a circuit substrate structure. The structure comprises a carrier, at least one attached enhancement portion, wherein the attached enhancement portion is to form rough surfaces on a surface of the carrier by utilizing the roughing process manner, and the rough surfaces of the attached enhancement portion being exposed, and a metal layer disposed on the attached enhancement portion. The metal layer is formed by reacting a catalyst preset on the attached enhancement portion with chemical plating solution.

Preferably, the circuit substrate structure further includes at least one conductive contact. The conductive contact is also disposed on the carrier through the roughing process manner and disposed at an outside of the attached enhancement portion. The conductive contact is connected to an edge of the carrier to form an interlinked circuit together with the attached enhancement portion.

The circuit substrate structure further includes an electroplating layer. An anti-plating insulation layer is further disposed on the conductive contact. The electroplating layer is disposed on the attached enhancement portion by utilizing the electrifying and electroplating, thereby increasing the thickness of the metal layer of circuit patterns. Finally, the anti-plating insulation layer and the metal layer on the conductive contact are removed to obtain independently circuit patterns.

According to another objective of the invention, the method for manufacturing circuit substrate structure is utilized to produce a circuit substrate structure. The structure comprises a carrier, a catalyst insulation layer, at least one attached enhancement portion and a metal layer. The catalyst insulation layer is penetrated to form the attached enhancement portion on the surface of the carrier so as to form the rough surface. The rough surface of the attached enhancement portion be exposed, and a metal layer is disposed to the attached enhancement portion. The metal layer is formed by reacting the catalyst that is preset to the attached enhancement portion with chemical plating solution.

The circuit substrate structure further includes at least one conductive contact and an electroplating layer. The conductive contact is disposed on the surface of the carrier by penetrating through the catalyst insulation layer through the roughing process and arranged at an outside of the attached enhancement portion. The conductive contact is connected to an edge of the carrier to form an interlinked circuit together with the attached enhancement portion. The conductive contact is used for connecting an edge of the carrier and the attached enhancement portion to form the metal layer by performing chemical plating. An anti-plating insulation layer is disposed to the metal layer of the conductive contact to isolate the conductive contact so as to prevent metal from being precipitated. The electroplating layer is formed by utilizing the electrifying and electroplating to increase the thickness of the metal layer. Finally, the anti-plating insulation layer and the metal layer on the conductive contact are removed to obtain independently circuit patterns.

The circuit substrate structure and its manufacturing method provided by the invention have the following advantages:
1. In a conventionally three-dimensional circuit process, since mass of catalysts or accelerators and chemical plating solution are required to add in the polymer plastic material, it may cause higher production costs. The non-conductive carrier of the invention does not contain metal oxides or the accelerator. After forming localized rough surfaces through laser irradiation etching, the catalyst can be merely attached to an area of the surface of the carrier to effectively reduce the catalyst used in the polymer plastic material during the circuit process.
2. A conventional method of activating metal oxides or the accelerators to produce the metal core through LDS laser needs higher concentration for reduction agents to start plating the metal core with respect to the reaction of chemically plating copper, thereby causing defects of unsteady, shorter service life, increased expenses, higher production costs relative to the plate solution of chemical copper. The invention uses laser irradiation etching to form the roughness attached portion that can effectively absorb the catalyst so as to facilitate forming the subsequent metal layer. The use of the catalyst and the accelerator can be reduced to have advantages of lower production costs, thereby greatly decreasing the using costs of the catalyst, the accelerator and chemical plating solution.

### BRIEF DESCRIPTION OF THE DRAWINGS

FIG. 1 is a flowchart of a method for manufacturing circuit substrate structure according to a first embodiment of the invention;

FIG. 2 is a structural schematic diagram of a circuit substrate structure according to a first embodiment of the invention;

FIG. 3 is a flowchart of a method for manufacturing circuit substrate structure according to a second embodiment of the invention;

FIG. 4 and FIG. 5 are structural schematic diagrams of a circuit substrate structure according to a second embodiment of the invention;

FIG. 6 is a flowchart of a method for manufacturing circuit substrate structure according to a third embodiment of the invention;

FIG. 7 is a structural schematic diagram of a circuit substrate structure according to a third embodiment of the invention;

FIG. 8 and FIG. 9 are structural schematic diagrams of a circuit substrate structure according to a fourth embodiment of the invention;

FIG. 10 is a structural schematic diagram of a circuit substrate structure according to a fifth embodiment of the invention;

FIG. 11 is a structural schematic diagram of a circuit substrate structure according to a sixth embodiment of the invention;

FIG. 12 is a structural schematic diagram of a circuit substrate structure according to a seventh embodiment of the invention;

FIG. 13 and FIG. 14 are structural schematic diagrams of a circuit substrate structure according to an eighth embodiment of the invention;

FIG. 15 and FIG. 16 are structural schematic diagrams of a circuit substrate structure according to a ninth embodiment of the invention.

### DETAILED DESCRIPTION OF THE PREFERRED EMBODIMENTS

The foregoing and other technical characteristics of the present invention will become apparent with the detailed description of the preferred embodiments and the illustration of the related drawings.

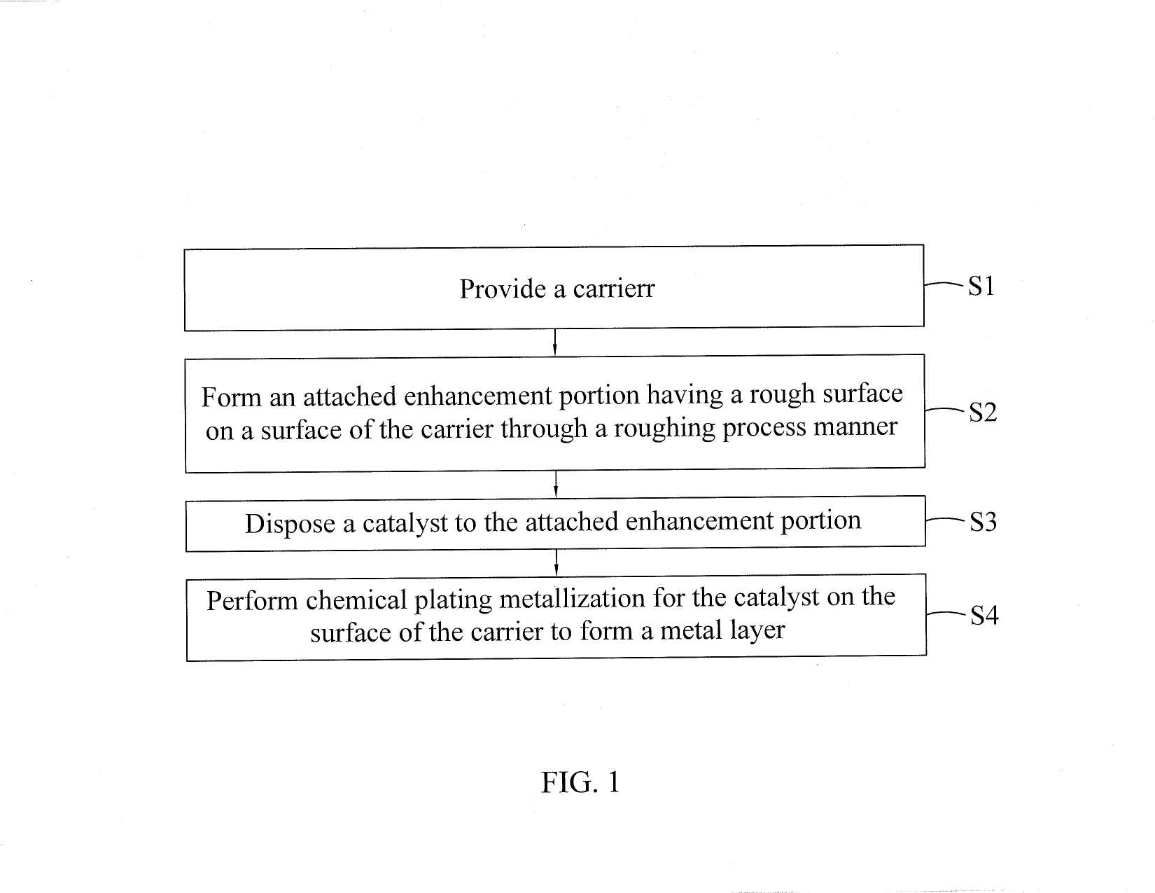

The invention provides a circuit substrate structure and its manufacturing method. With reference to FIG. 1 for a flowchart of a manufacturing method for circuit substrate structure according to a first embodiment of the invention is depicted.

The steps of the manufacturing method for circuit substrate structure of the invention mainly comprise:

Step S1, firstly provide a carrier, wherein the carrier can be a non-conductive carrier.

Step S2, form an attached enhancement portion having a rough surface on a surface of the carrier through a roughing process manner.

Step S3, dispose a catalyst to the attached enhancement portion, wherein the manner of forming the catalyst is that the carrier is immersed into a catalyst solution tank to attach the catalyst on the attached enhancement portion.

Step S4, finally perform chemical plating metallization for the catalyst on the surface of the carrier to form a metal layer.

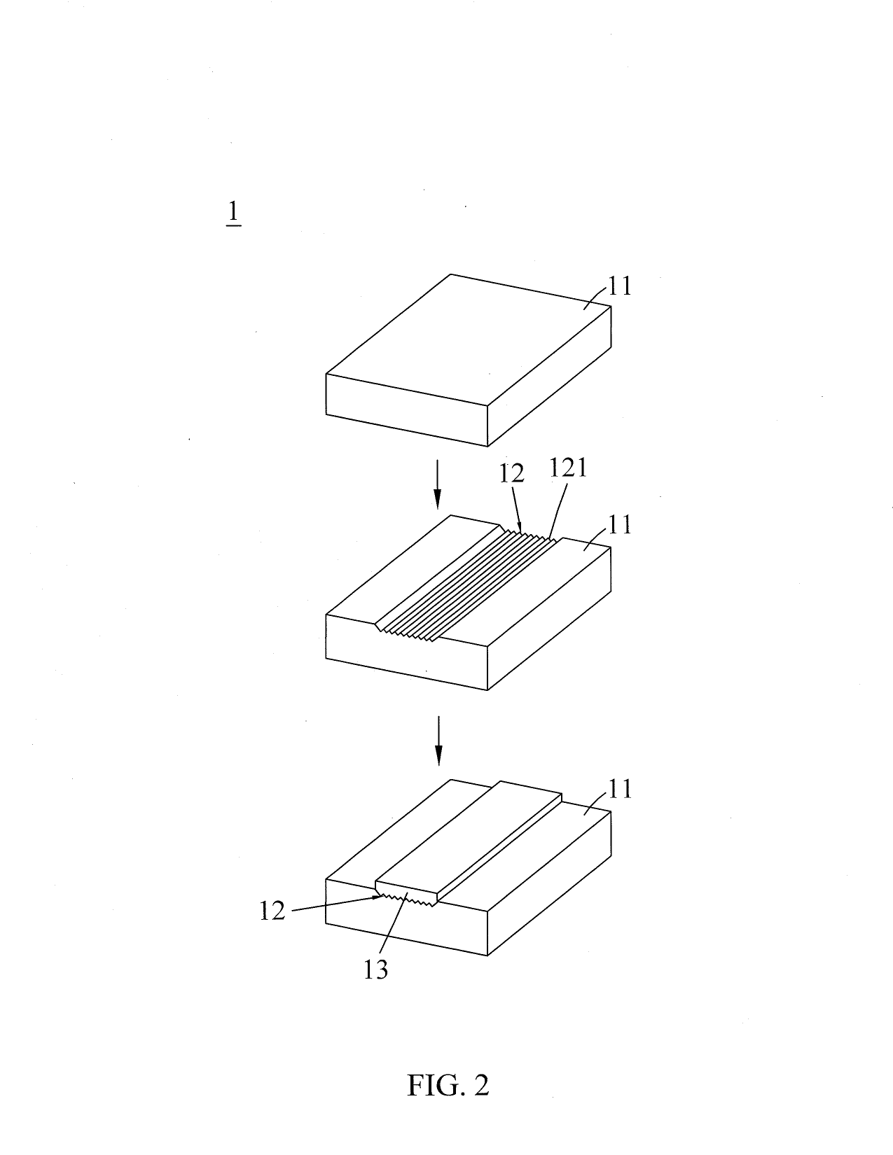

In FIG. 1, the attached enhancement portion performed by the step S2 is displayed by an imaging result taken from an electron microscopy and has uneven and rough shape. With reference to FIG. 2 for the attached enhancement portion, which has been treated by roughness process, on the surface of the carrier is obtained by the detection of a scanning electron microscopy (so called SEM), wherein its pore size is about 10 to 20 μm.

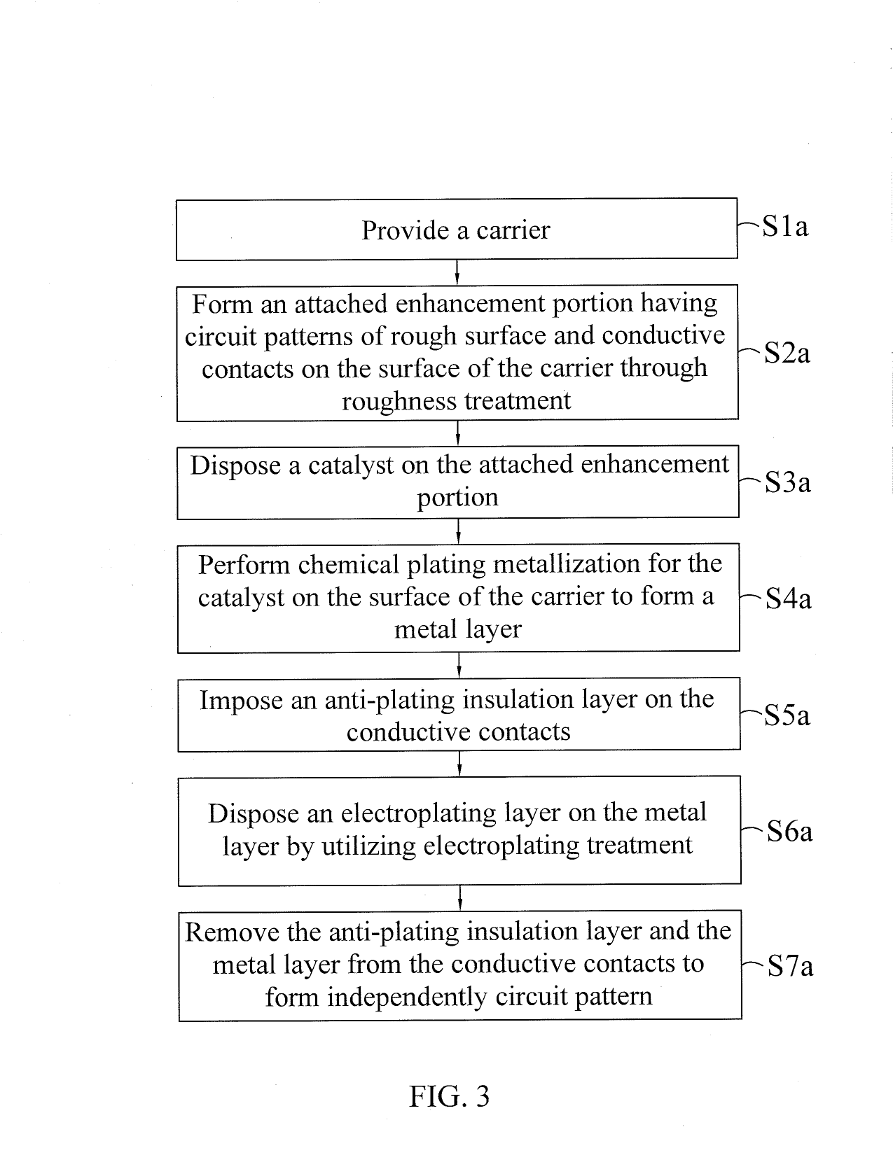

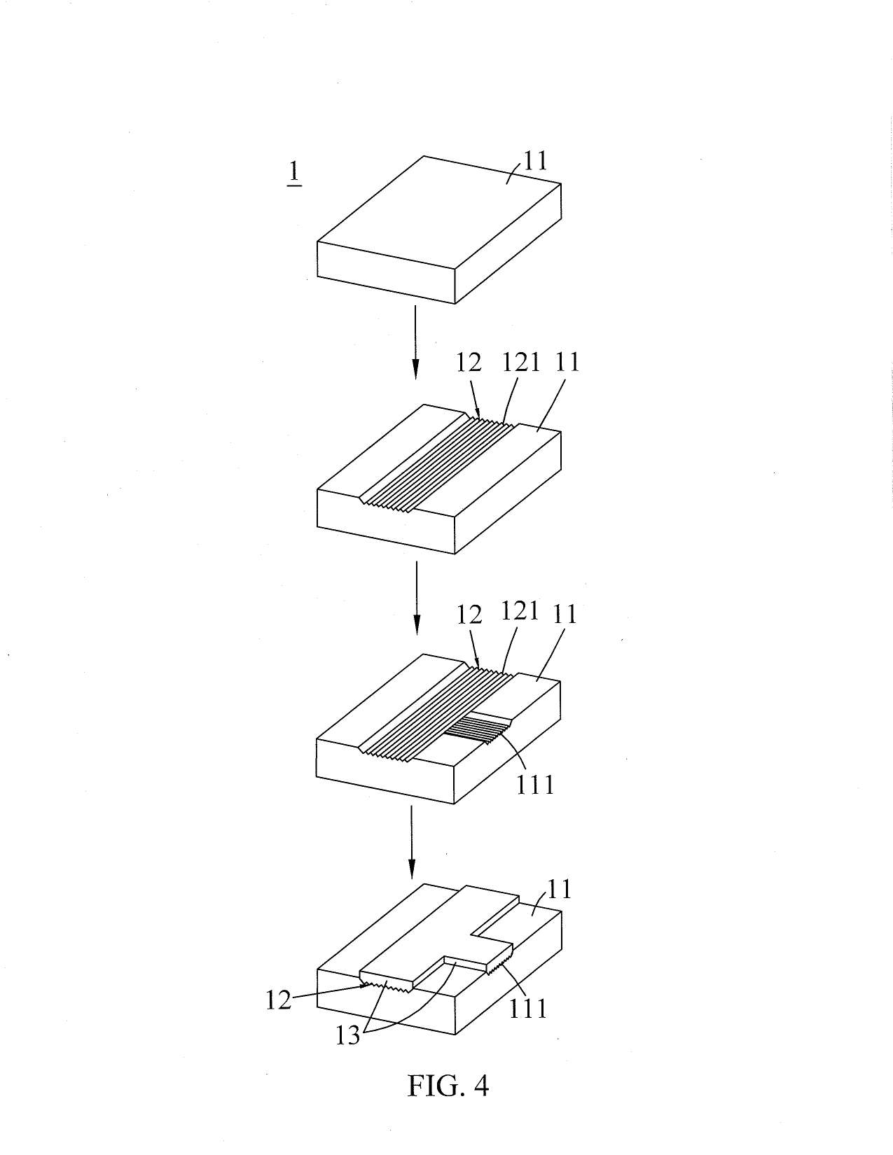

With reference to FIG. 3 and FIG. 4, the surface of the carrier is cleaned up in the step S3 to clean matters, such as grease and dirts, on the surface of the carrier. The embodiment adopts immersing the carrier into a diluted detergent (containing surfactant) for degreasing to clean the surface of the carrier, and the property of the rough surface of the attached enhancement portion is converted into hydrophilicity from hydrophobicity, and the carrier then is rinsed by pure water.

Further, the image for dewdrops attached to the surface of the carrier can be captured by the SEM. As shown in FIG. 4, in a right side of the figure, dewdrops are dropped on the surface of the carrier that is not treated with roughness process, dewdrops do not have attachment and absorption phenomenon so as to form water drops. A left side of the figure is the attached enhancement portion, which has been treated with roughness process, on the surface of the carrier, and water drops have attachment and diffusion phenomenon so that the property of the attached enhancement portion is converted into hydrophilicity from hydrophobicity. It represents that more catalysts can absorb and be firmly attached to the attached enhancement portion to facilitate subsequent chemical coating reaction.

The catalyst adopted in the step S3 can be selected from a group consisting of titanium, antimony, silver, palladium, iron, nickel, copper, vanadium, cobalt, zinc, platinum, iridium, osmium, rhodium, rhenium, ruthenium, tin or the foregoing mixture and can, but not limited to, be a compound containing the foregoing elements such as palladous chloride (PdCl₂), stannic chloride (SnCl₂), palladium sulfate hydrate (II) and the like.

In the step S4, the catalyst on the surface of the carrier can be chemically plated with at least one layered of metal layer through chemical reduction reaction by adopting copper or nickel. The metal layer can also be taken as an initial conductive film prior to performing electroplating procedure for a non-conductive carrier so as to provide a normal electric electroplating procedure with respect to copper, nickel and chromium. In the invention, the metal layer can be any metal or alloy having excellent conductivity. The embodiment adopts copper to react with the catalyst to form the metal layer. The manufacturing method for circuit substrate structure depicted in the steps S1 to S4 can be widely applied to a three-dimensional or planar circuit process with non-conductive carriers.

With reference to FIG. 2 for a circuit substrate structure of the first embodiment made of the steps S1 to S4 shown in FIG. 1 is depicted. As shown in the figure, the circuit substrate structure 1 of the invention is suitable for a circuit structure. The circuit substrate structure 1 includes a carrier 11 and at least one attached enhancement portion 12, wherein each attached enhancement portion 12 is formed with a rough surface 121 on the surface of the carrier through a roughing process manner (the embodiment adopts laser irradiation etching). The rough surface 121 of each attached enhancement portion 12 being exposed. Afterward the carrier 11 is immersed into a catalyst solution tank to attach the catalyst on the attached enhancement portion 12. Finally, the catalyst on the surface of the carrier 11 is performed with chemical plating metallization to form a metal layer 13. The metal layer 13 includes at least one circuit pattern.

In the invention, the metal layer can be taken as the initially conductive film prior to performing electroplating on the non-conductive carrier. To further understand the technical means applied to electroplating treatment in the invention, the processing flow for performing electroplating on the metal layer is specifically depicted herein. With reference to FIG. 3 for a flowchart of electroplating applied to the schematic diagram according to a second embodiment of the invention is depicted. The steps are shown as the following:

Step S1a, firstly provide a carrier, wherein the carrier can be a non-conductive carrier.

Step S2a, form an attached enhancement portion having circuit patterns of rough surface and conductive contacts on the surface of the carrier through roughness treatment.

Step S3a, dispose a catalyst on the attached enhancement portion, wherein a manner of forming the catalyst is that the carrier is immersed into a catalyst solution tank to attach the catalyst on the attached enhancement portion.

Step S4a, perform chemical plating metallization for the catalyst on the surface of the carrier to form a metal layer.

Step S5a, impose an anti-plating insulation layer on the conductive contacts.

Step S6a, dispose an electroplating layer on the metal layer by utilizing electroplating treatment.

Step S7a, finally remove the anti-plating insulation layer and the metal layer from the conductive contacts to form independently circuit pattern.

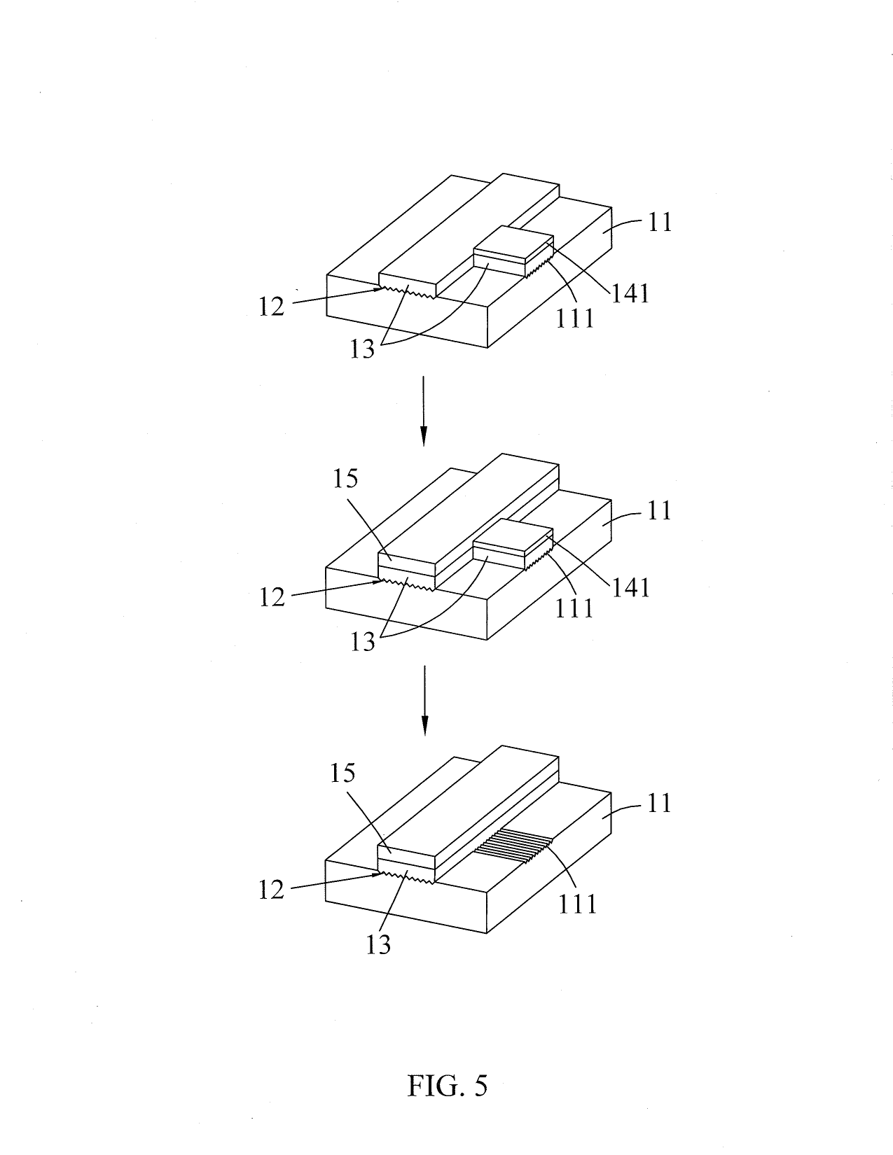

With reference to FIG. 4 and FIG. 5 for a circuit substrate structure made of the steps S1a to S7a shown in FIG. 3 is depicted. As shown in FIG. 4, the circuit substrate structure 1 of the invention is suitable for a circuit structure. The circuit substrate structure 1 includes a carrier 1 and at least one attached enhancement portion 12, wherein each attached enhancement portion 12 is disposed on the surface of the carrier 11 through roughness treatment (the embodiment adopts laser irradiation etching) to form a rough surface 121 of each attached enhancement portion 12. The rough surface 121 of each attached enhancement portion 12 being exposed. The surface of the carrier 11 is further disposed with a conductive contact 111. Each conductive contact 111 is connected to an edge of the carrier 11 and each attached enhancement portion 12. Since the conductive contact 111 is connected to the edge of the carrier 11 and each attached enhancement portion 12, chemical plating is performed to form a metal layer 13. As shown in FIG. 5, an anti-plating insulation layer 141 is further imposed on each conductive contact 111. The thickness of the metal layer 13 on the attached enhancement portion 12 is increased by utilizing electroplating so as to form an electroplating layer 15. Finally, the anti-plating insulation layer 141 on each conductive contact 111 and the metal layer 13 are removed to form independently circuit patterns.

During the electroplating, the metal layer 13 having conductivity generated by electroplating and electrifying is taken as a cathode, and an anode with power is jointed to a pre-plated metal solid. When the carrier 11 is immersed into electroplating solution containing pre-plated metal ions, the pre-plated metal ions are reduced to precipitate pre-plated metal on the metal layer 13 when the metal layer 13 taken as the cathode receives electrons, thereby forming the required metal circuits. The pre-plated metal can be copper, nickel, chromium, tin, silver or gold or other alloy metal.

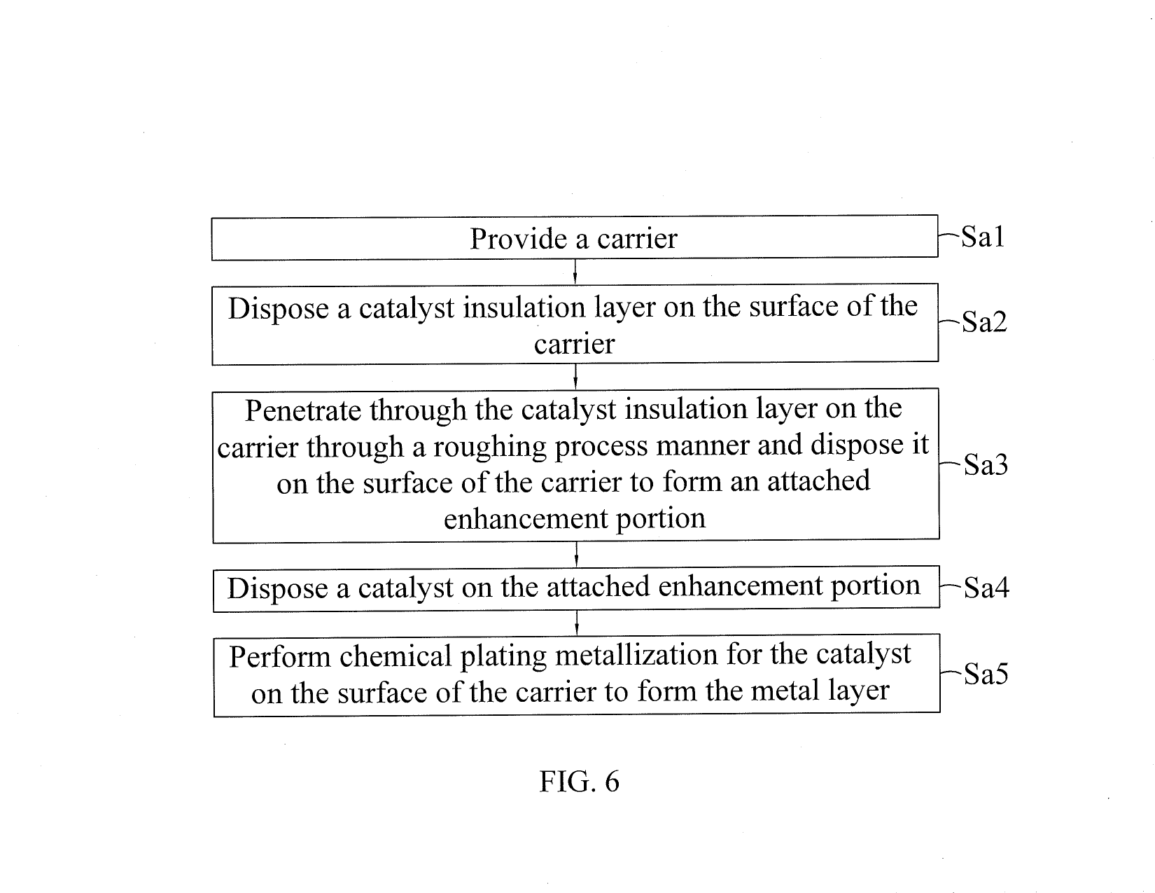

Since the surface of the carrier does not have an active catalyzed layer, the surface may be easily reacted with the catalyst and the chemical plating solution due to its material property. With reference to FIG. 6 for a flowchart of a manufacturing method for circuit substrate structure according to a third embodiment of the invention is shown as the following:

Step Sa1, firstly provide a carrier, wherein the carrier can be a non-conductive carrier.

Step Sa2, dispose a catalyst insulation layer on the surface of the carrier.

Step Sa3, penetrate through the catalyst insulation layer on the carrier through a roughing process manner and dispose it on the surface of the carrier to form an attached enhancement portion.

Step Sa4, dispose a catalyst on the attached enhancement portion, wherein a manner of forming the catalyst is to immerse the carrier into a catalyst solution tank to attach the catalyst on the attached enhancement portion.

Step Sa5, finally perform chemical plating metallization for the catalyst on the surface of the carrier to form the metal layer.

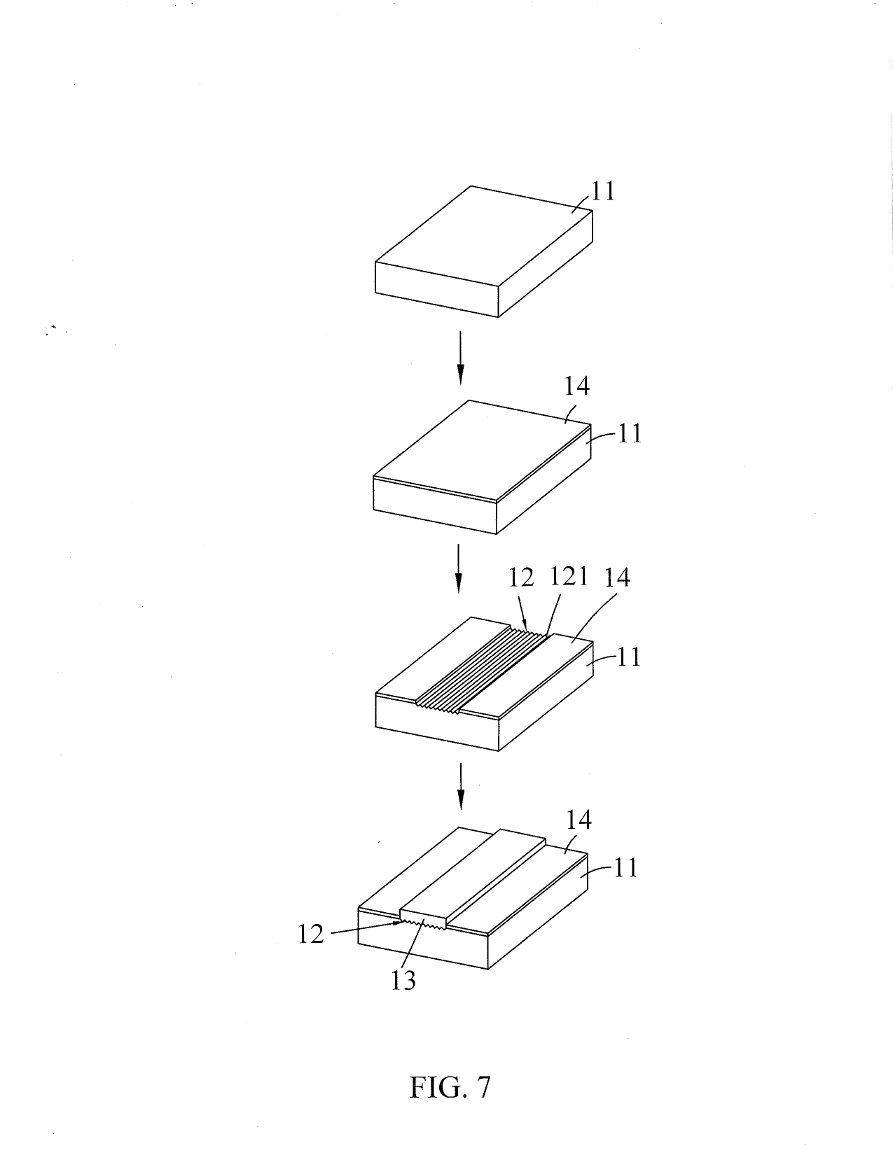

In another word, the circuit substrate structure in the third embodiment of the invention is identical the first embodiment. The difference between both is that the catalyst insulation layer 14 (as shown in FIG. 7) is disposed on the surface of the carrier 11 prior to the step S2.

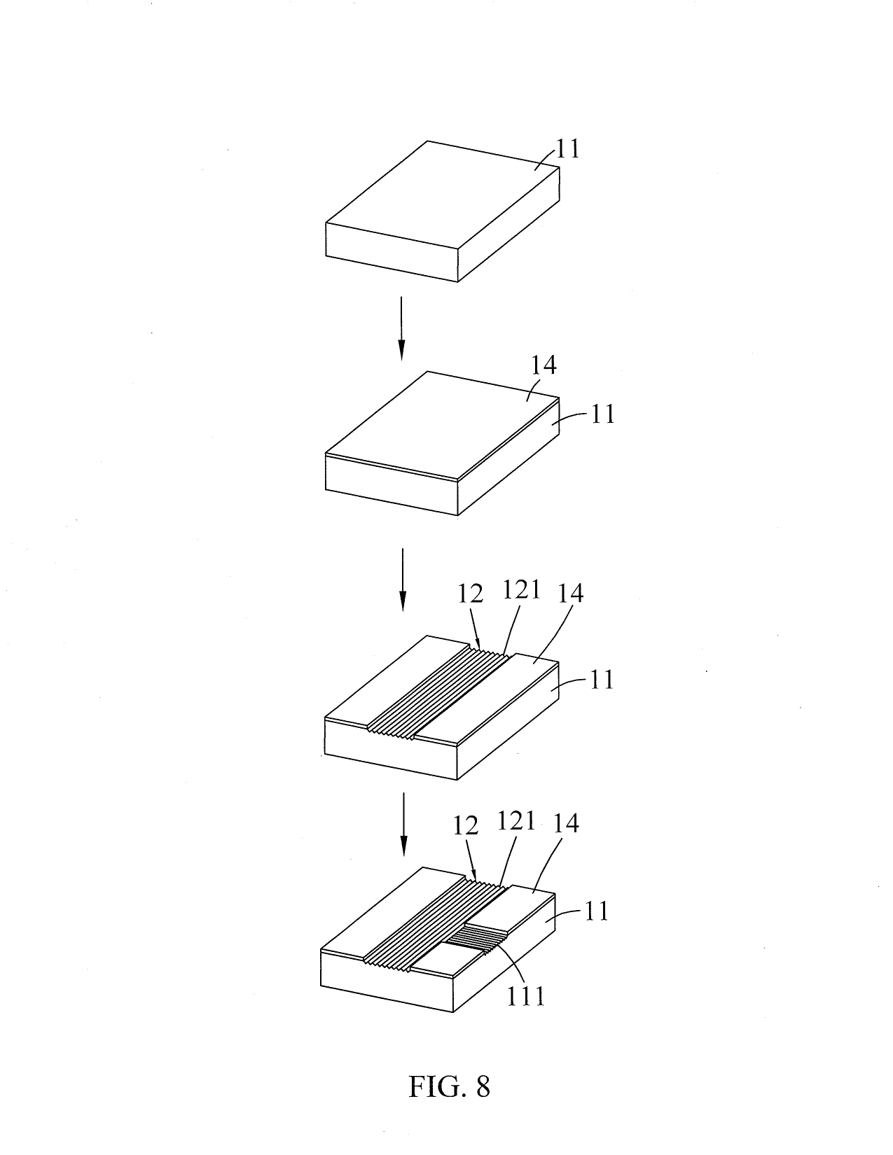

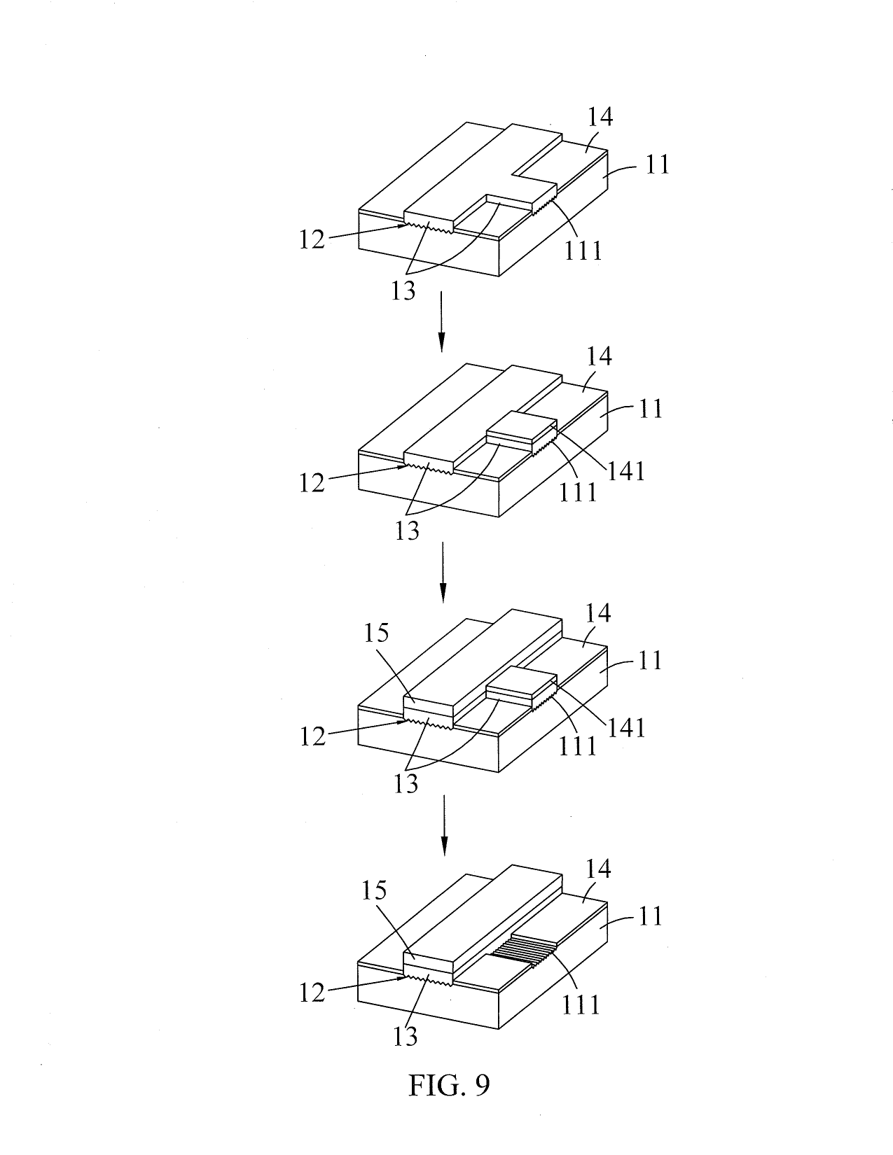

Further, with reference to FIG. 8 and FIG. 9, the flowchart of the manufacturing method for circuit substrate structure in the fourth embodiment of the invention is identical the second embodiment. The difference between both is that the catalyst insulation layer 14 is disposed on the surface of the carrier 11 prior to the step 2a, and the catalyst insulation layer 14 on the carrier is penetrated by a roughing process and disposed on the surface of the carrier to form each attached enhancement portion. The subsequent steps are identical the steps S2a to S7a.

The catalyst insulation layer 15 can be formed by using a photoresist agent, ink or paints by means of printing and ink-printing or pasting insulated tapes or taking a dry film photoresist agent as the catalyst insulation layer 14, wherein the catalyst insulation layer 14 can be removed or not be removed.

In the foregoing embodiments, the carrier is immersed into the catalyst solution tank, and a main constituent of the catalyst solution can be palladous chloride, tin chloride and hydrochloric acid (PdCl₂+SnCl₂+HCl) to form an extra thin catalyst having catalysis on the attached enhancement portion. Since tin ions of the material surface of the carrier would become Sn(OH)₄ without catalysis, the Sn(OH)₄ would have the catalysis for colloid attenuated palladium (Pd) metal particles. By peeling off the “tin shell”, a metal state Pd reduced from the surface of the carrier is taken as a catalyst for subsequent chemical plating. The foregoing process is so called accelerator.

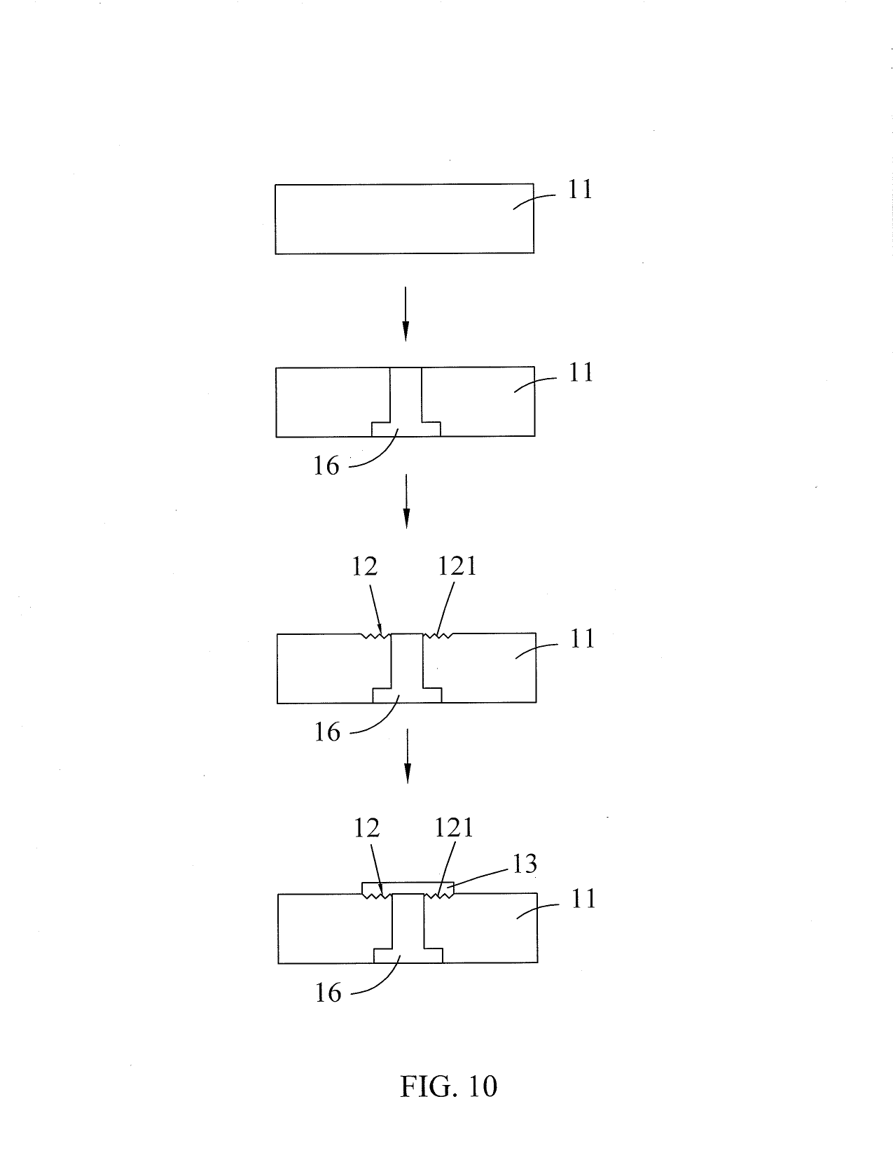

Moreover, to increase the heat transfer efficiency of the whole circuit substrate structure, a heat conduction column can be embedded in the carrier. With reference to FIG. 10 for a flowchart of a manufacturing method for circuit substrate structure according to a fifth embodiment of the invention is depicted. The flowchart is the same as the first embodiment. A difference between both is that a heat conduction column 16 is embedded to the carrier 11 prior to the step S2. In the step S2, the attached enhancement portion 12 having the rough surface 121 is formed at a surface of the carrier 11 corresponding to a position of the heat conduction column 16 and a circumference of the heat conduction column 16 through a roughing process manner. The heat conduction column embedded in the carrier is that at least one heat conduction column is embedded in a high heat source of the carrier based upon product demand designed by producers, thereby increasing heat transfer efficiency of the overall circuit substrate structure.

Moreover, the material of the heat conduction column can, but not limited to, be selected from a group consisting of lead, aluminum, gold, copper, tungsten, magnesium, molybdenum, zinc, silver, graphite, graphite alkene, diamond, carbon nano-tube, carbon nano-capsule, nano-bubble, carbon sixty, carbon nano-cone, carbon nano-horn, carbon nano-pipet, tree-like carbon micrometer structure, beryllium oxide, aluminum oxide, zirconium oxide, boron nitride, aluminum nitride, magnesium oxide, silicon nitride, silicon carbide or a foregoing combination.

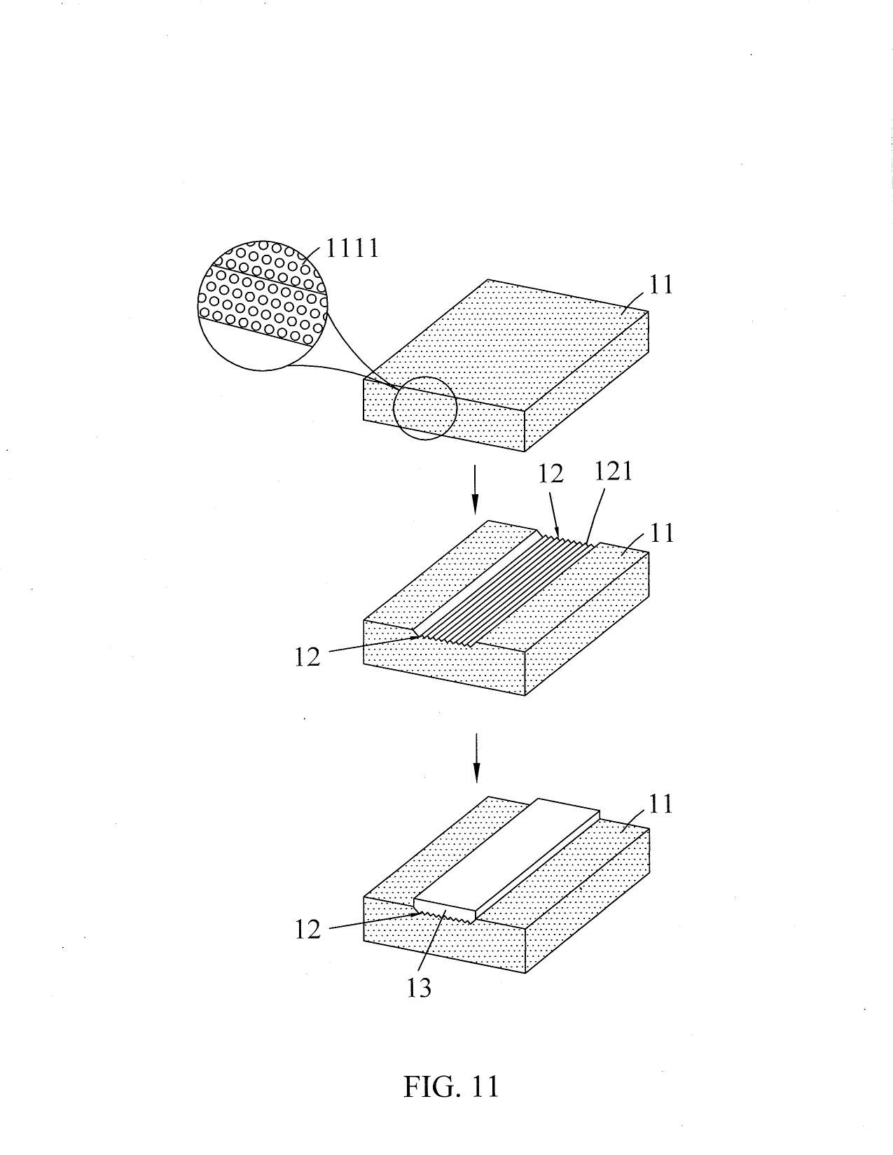

With reference to FIG. 11 for a schematic diagram of a circuit substrate structure according to a sixth embodiment of the invention is depicted. The diagram is equivalent to the purpose of the foregoing fifth embodiment and to increase the heat transfer efficiency of the overall circuit substrate substrate, and a heat conduction material can be added in the carrier. Its structure depicted in the sixth embodiment is the same as the first embodiment (FIG. 2). The difference between both is that the heat conduction material 1111 has been added and is uniformly mixed in the carrier 11 while performing the step S1 of providing the carrier 11. Afterward the added enhancement portion 12 having the rough surface 121 is formed by a roughing process manner. The subsequent steps are the same as the first embodiment.

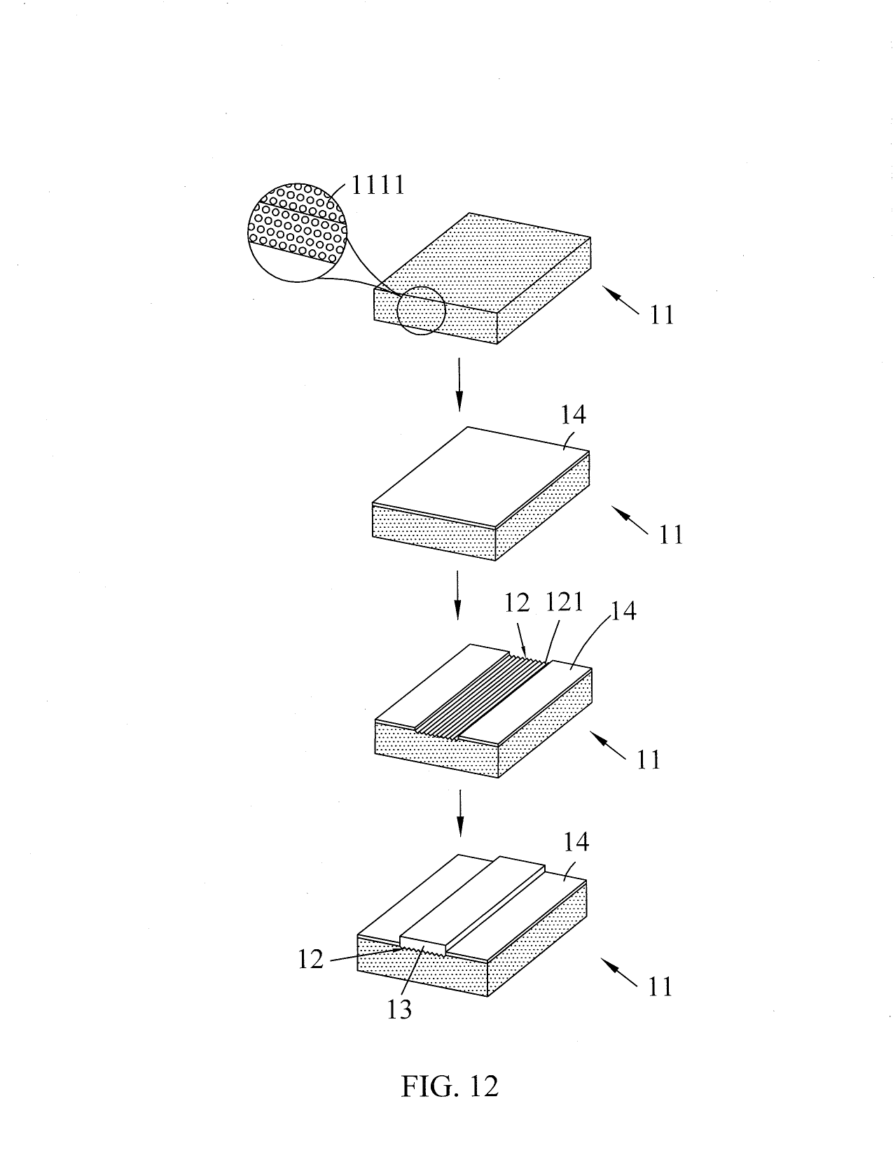

With reference to FIG. 12 for a schematic diagram of a circuit substrate structure according to a seventh embodiment of the invention is depicted. Its structure is equivalent to the third embodiment. The difference between both is that the heat conduction material 1111 has been added and is uniformly mixed in the carrier 11 while performing the step 1 of providing the carrier 11. Afterward the catalyst insulation layer 14 is firstly disposed on the surface of the carrier 11 prior to the step 2. The surface of the carrier 11 can be isolated to prevent the surface of the carrier 11 from being easily reacted with the catalyst and chemical plating solution due to its material property.

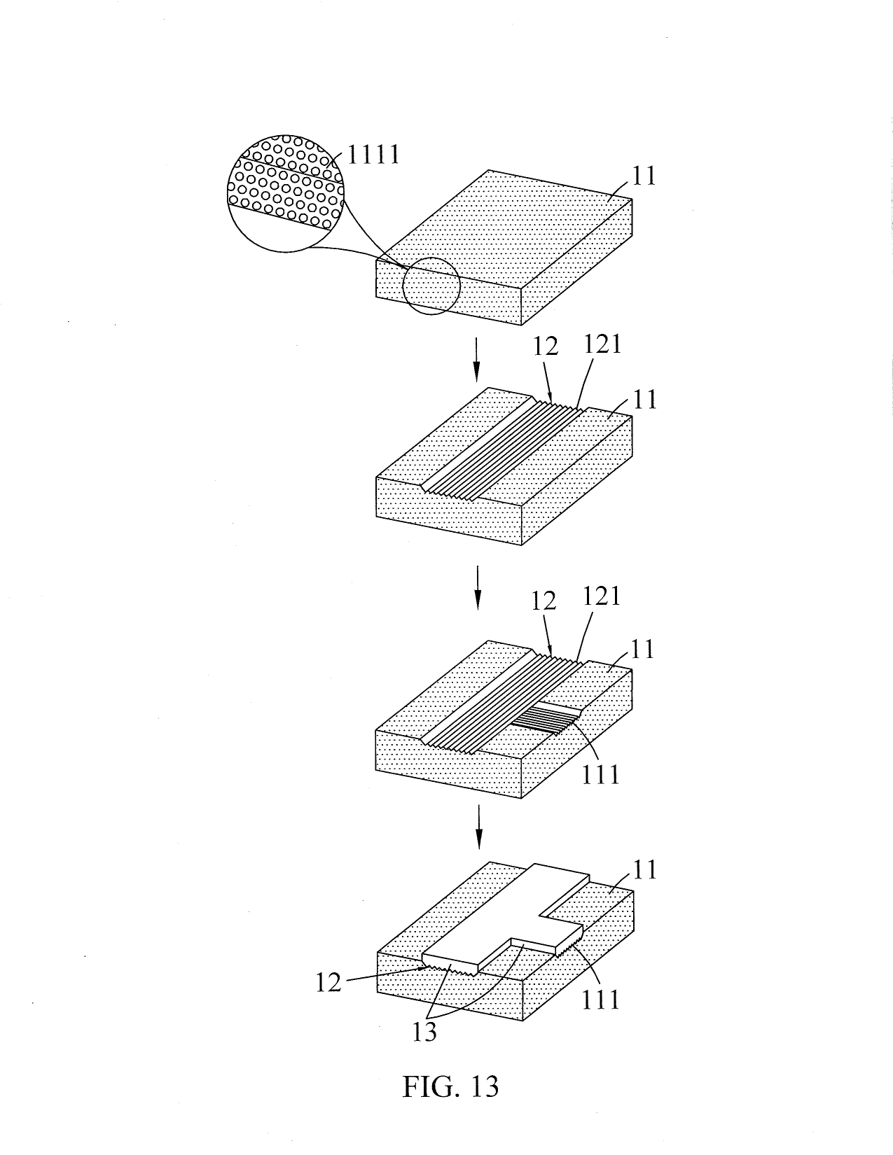

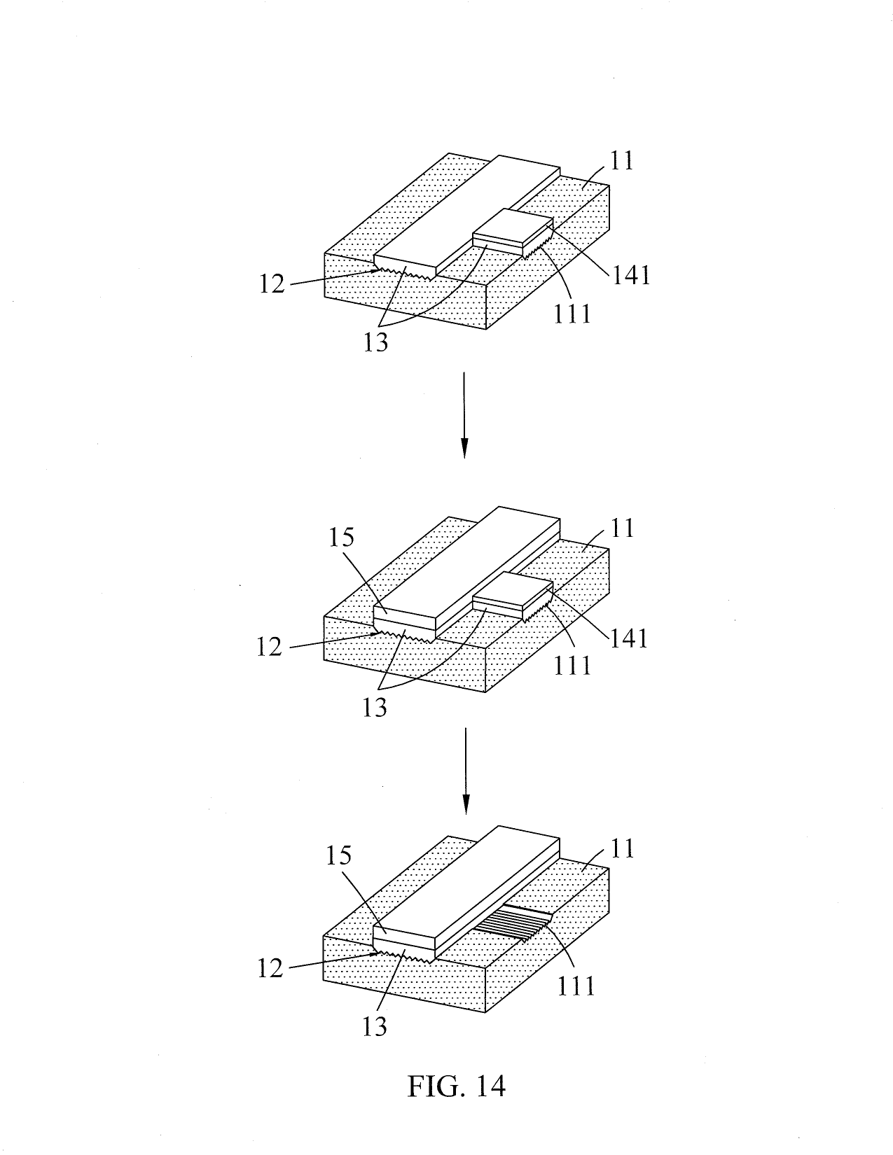

With reference to FIG. 13 to FIG. 14 for schematic diagrams of a circuit substrate structure according to an eighth embodiment of the invention is depicted, and the diagrams are another type (FIG. 4 to FIG. 5) according to the second embodiment. The difference between both is that the heat conduction material 1111 is added and uniformly mixed in the carrier 11 while performing the step S1 of providing the carrier 11. The subsequent steps are the same as the second embodiment.

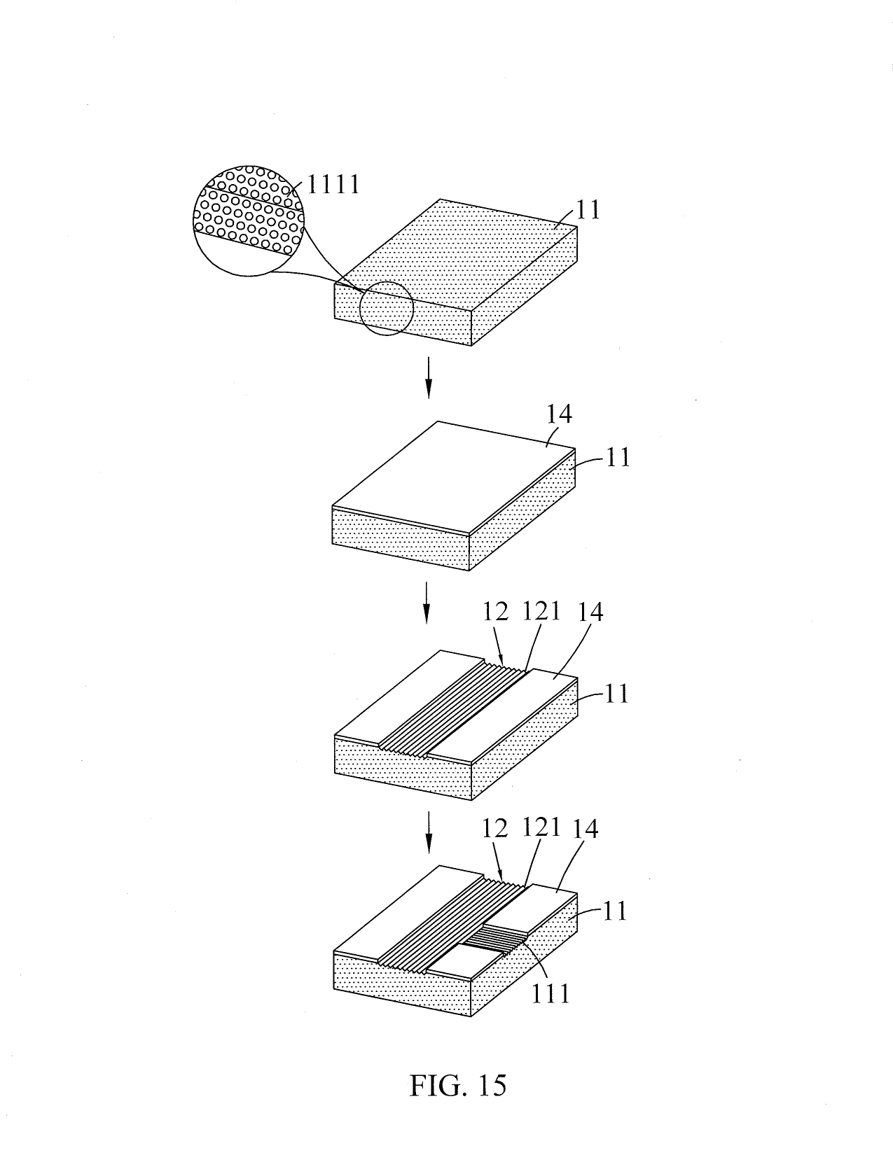

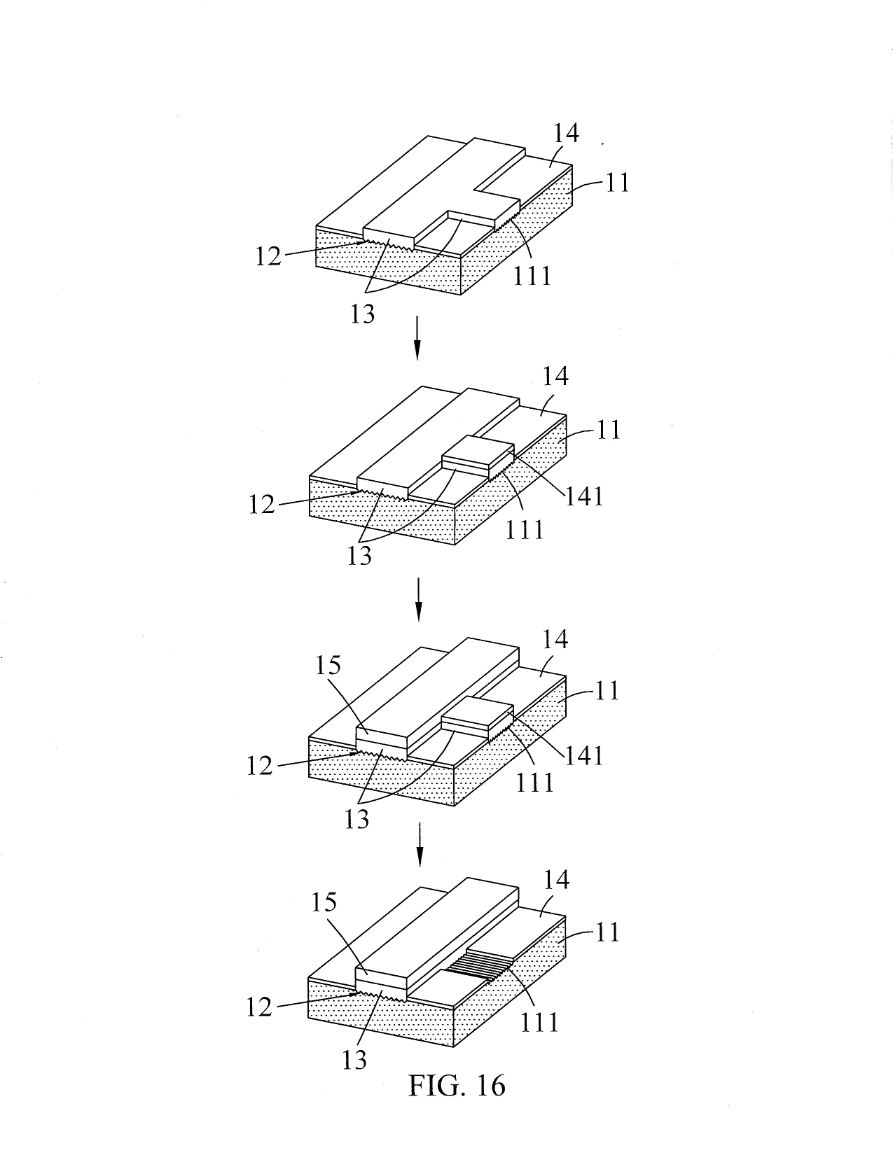

With reference to FIG. 15 to FIG. 16 for schematic diagrams of a circuit substrate structure according to a ninth embodiment of the invention are depicted. The diagrams are another type (FIG. 8 and FIG. 9) according to the fourth embodiment. The difference between both is that the heat conduction material 1111 is added and uniformly mixed in the carrier 11 while performing the step of providing the carrier 11. The subsequent steps are the same as the fourth embodiment.

The sixth, seventh, eighth and ninth embodiments of the invention are to add the heat conduction material 1111 in the carrier 11. The added quantity and types can be properly regulated according to product demands designed by producers. The purpose is to increase the heat transfer efficiency of the overall circuit substrate structure.

The material adopted in the non-conductive carrier of the invention can be a polymer plastic material or a ceramic material. The polymer plastic material can be a thermoplastic plastic material or thermosetting plastic material. The material of the non-conductive carrier has a thermal conduction property, and an inorganic filler can be added into the polymer plastic material of the non-conductive carrier, wherein the constituent of the inorganic filler can be selected from a group consisting of silicic acid, silicic acid derivative, carbonic acid, carbonic acid derivative, phosphoric acid, phosphoric acid derivative, active carbon, porous carbon, carbon black, glass fabrics, carbon fabrics or mineral fabrics or a foregoing combination. Further, the ceramic material can be selected from a group consisting of oxide, nitride, carbide, or boride. Moreover, the ceramic material is selected from a group consisting of oxide, nitride, carbide, and boride is combined with a binding agent to form a mixture capable of being injected and pressed. After forming the mixture, the binding agent is removed to sinter it.

The roughing process adopted in the invention can use manners, such as sandblasting or laser irradiation etching, to dispose the attached enhancement portion having roughness on the surface of the carrier. The wavelength range of the laser irradiation can be between 248 and 10600 nanometer, wherein the laser irradiation etching can, but not limited to, be carbon dioxide (CO₂) laser, yttrium aluminum garnet (Nd:YAG) laser, yttrium orthovanadate (Nd:YVO₄) laser, excimer laser or fiber laser.

In the invention, material having thermal conduction property or its derivative materials is dispersedly added in the non-conductive carrier. The material having thermal conduction property can be a metal heat conduction material or a non-metal heat conduction material. The metal heat conduction material can be selected from a group consisting of lead, aluminum, gold, copper, tungsten, magnesium, molybdenum, zinc or silver or a foregoing combination. The non-metal heat conduction material can, but not limited to, be selected from a group consisting of graphite, graphite alkene, diamond, carbon nano-tube, carbon nano-capsule, nano-bubble, carbon sixty, carbon nano-cone, carbon nano-horn, carbon nano-pipet, tree-like carbon micrometer structure, beryllium oxide, aluminum oxide, zirconium oxide, boron nitride, aluminum nitride, magnesium oxide, silicon nitride or silicon carbide or a foregoing combination.

The catalyst adopted in the embodiments can be selected from a group consisting of titanium, antimony, silver, palladium, iron, nickel, copper, vanadium, cobalt, zinc, platinum, iridium, osmium, rhodium, rhenium, ruthenium, tin or its mixture and can, but not limited to, also be a compound containing the foregoing elements such as palladous chloride (PdCl₂), tin chloride (SnCl₂) and palladium sulfate hydrate.

The method for manufacturing a circuit substrate structure depicted in the first to the ninth embodiment can be widely applied to various non-conductive carriers and can be a three-dimensional circuit process of a plastic film component having heat conduction property or a material having heat conduction property.

With reference to FIG. 5, data is obtained by performing EDS analysis for the carrier of the invention shown in FIG. 2. Data shows that the carrier of the invention is not doped with any metal oxide or accelerator. Gold (Au) element shown in the figure is that the non-conductive conductor must be firstly plated with gold layer during pretreatment to increase conductivity so that electron can be prevented from being accumulated to avoid affecting resolution due to the accumulation of electric charge.

With reference to FIG. 6, a SEM drawing of laser-engraving the surface of the carrier (LPKF) through conventional LPKF-LDS technique is depicted. LPKF carrier is doped with metal oxide compound. In addition, with reference to FIG. 7, according to data, the LPKF carrier is doped with metal oxide. Chromium (Cr) and copper (Cu) elements exists in the LPKF carrier shown in the EDS figure. The difference between technical features of the invention and prior arts is that the carrier of the invention does not contain any metal oxide. Therefore, after forming a regionalized rough surface through roughing process (laser irradiation etching), catalysts can be attached and firmly fastened to a roughed region of the surface of the carrier to effectively reduce catalyst quantity of the polymer plastic material used in a three-dimensional or planar circuit processes. The conventional technique uses LDS laser to activate metal oxide to produce metal core. Since the LPKF carrier contains metal oxide, the reduction agent concentration having higher dosage is required in the reaction of chemically plating copper so as to smoothly plate the metal core, thereby causing defects of unsteady, shorter service life, increased expenses, and higher production costs relative to the plate solution of chemical copper.

The circuit substrate structure and its manufacturing method of the invention forms the attached enhancement portion on the non-conductive carrier through laser irradiation etching so that the catalyst can be effectively sucked and firmly disposed to the attached enhancement portion to facilitate forming subsequent metal layers to have the advantage of lower production cost, capable of greatly reducing the usage of the catalyst and the accelerator and the cost of using chemical plate solution. Further, the problems of consuming higher production costs caused by conventionally activating the metal oxide through laser or producing the metal core through the accelerator can be improved.

It should be noted that in each embodiment of the invention, the attached enhancement portion, the catalyst, the metal layer, the anti-plating insulation layer, the catalyst insulation layer and the electroplating layer are disposed on one of single planes of the non-conductive carrier. While actually implementing the invention, different planes of the non-conductive carrier can, but not limited to, also be disposed with the attached enhancement portion, the catalyst, the metal layer, the anti-plating insulation layer, the catalyst insulation layer and the electroplating layer. In another word, the circuit substrate structure and its manufacturing method of the invention can produce three-dimensional or planar circuits.

Moreover, in each embodiment of the invention, before performing next step from each step, a cleaning motion is executed to prevent the manufacture procedure of next steps from being polluted by former steps. The foregoing technical means in the ordinary field is not depicted in the invention. For example, the attached enhancement portion having rough surfaces is formed on the non-conductive carrier through roughing process to produce scraps remained on the non-conductive carrier. The scraps can be removed from the surface of the non-conductive carrier by using the cleaning motion. However, it should be noted that the non-conductive carrier is immersed into a catalyst solution tank to attach the catalyst on the attached enhancement portion. After cleaning, the catalyst can be attached to the attached enhancement portion because of the rough surface of the attached enhancement portion. The catalyst on a portion of the non-conductive carrier that does not have the attached enhancement portion is removed through cleaning motion. Alternatively, the residue of the catalyst may not easily react with chemical plating or its reaction does not influence the circuit quality of the circuit substrate structure.

The invention improves over the prior art and complies with patent application requirements, and thus is duly filed for patent application. While the invention has been described by device of specific embodiments, numerous modifications and variations could be made thereto by those generally skilled in the art without departing from the scope and spirit of the invention set forth in the claims.

What is claimed is:

1. A method for manufacturing circuit substrate structure suitable for circuit process of a non-conductive carrier, the method comprising steps of:
providing a carrier;
forming an attached enhancement portion having rough surfaces on a surface of the carrier through a roughing process;
disposing a catalyst on the attached enhancement portion; and
reacting the catalyst through chemical plating reduction to further form a metal layer on the attached enhancement portion.

2. The method for manufacturing circuit substrate structure as recited in claim 1, wherein the roughing process is sand blasting or laser irradiation etching.

3. The method for manufacturing circuit substrate structure as recited in claim 1, wherein before performing the roughing process on the surface of the carrier, a catalyst insulation layer is further disposed on the carrier, and the roughing process is used to further pierce through the catalyst insulation layer so as to form the attached enhancement portion on the surface of the carrier.

4. The method for manufacturing circuit substrate structure as recited in claim 1, wherein the carrier is made of a non-conductive material as a non-conductive carrier, and the non-conductive material includes a polymer plastic material or a ceramic material.

5. The method for manufacturing circuit substrate structure as recited in claim 1, wherein the catalyst is selected from a group consisting of titanium, antimony, silver, palladium, iron, nickel, copper, vanadium, cobalt, zinc, platinum, iridium, osmium, rhodium, rhenium, ruthenium, tin a mixture thereof and a compound thereof.

6. The method for manufacturing circuit substrate structure as recited in claim 4, wherein the polymer plastic material includes inorganic filler.

7. The method for manufacturing circuit substrate structure as recited in claim 4, wherein the non-conductive carrier comprises a material having heat conduction property or a derivative thereof dispersed therein.

8. The method for manufacturing circuit substrate structure as recited in claim 7, wherein the material of the non-conductive carrier having heat conduction property includes a metal conduction material.

9. The method for manufacturing circuit substrate structure as recited in claim 7, wherein the material of the non-conductive carrier having heat conduction property includes a non-metal conduction material.

10. The method for manufacturing circuit substrate structure as recited in claim 4, wherein a heat conduction column is embedded in the non-conductive carrier.

11. The method for manufacturing circuit substrate structure as recited in claim 1, further comprising steps of:
disposing at least one conductive contact on the carrier, which is at an outside of the attached enhancement portion, through the roughing process after providing the carrier, the conductive contact connected to an edge of the carrier to form an interlinked circuit together with the attached enhancement portion;
disposing the metal layer on the attached enhancement portion through chemical electroplating;
disposing an anti-plating insulation layer on the conductive contact;
utilizing electroplating to dispose an electroplating layer on the metal layer;
removing the anti-plating insulation layer and the metal layer from the conductive contact to obtain an independently circuit pattern.

12. A circuit substrate structure comprising:
a carrier;
at least one attached enhancement portion, a rough surface of the attached enhancement portion being formed on a surface of the carrier, the rough surface of the attached enhancement portion being exposed; and
a metal layer disposed to the attached enhancement portion, the metal layer being formed by reacting a catalyst preset to the attached enhancement portion with chemical plating solution.

13. The circuit substrate structure as recited in claim 12, further comprising at least one conductive contact connected to an edge of the carrier to form an interlinked circuit together with the attached enhancement portion.

14. The circuit substrate structure as recited in claim 13, wherein an anti-plating insulation layer is disposed on the metal layer of the conductive contact.

15. The circuit substrate structure as recited in claim 14, wherein an electroplating layer is disposed on the metal layer.

16. A circuit substrate structure comprising:
a carrier;
a catalyst insulation layer disposed on a surface of the carrier;
at least one attached enhancement portion with a rough surface, the attached enhancement portion piercing through the catalyst insulation layer and disposed on the surface of the carrier, the rough surface of the attached enhancement portion being exposed; and
a metal layer disposed on the attached enhancement portion, the metal layer formed by reacting a catalyst preset to the attached enhancement portion with chemical plating solution.

17. The circuit substrate structure as recited in claim 16, further comprising at least one conductive contact connected to an edge of the carrier to form an interlinked circuit together with the attached enhancement portion.

18. The circuit substrate structure as recited in claim 17, wherein an anti-plating insulation layer is disposed on the metal layer of the conductive contact.

19. The circuit substrate structure as recited in claim 18, wherein an electroplating layer is disposed on the metal layer.
